(19) United States
(12) Patent Application Publication
(10) Pub. No.: US 2025/0273523 A1
(43) Pub. Date: Aug. 28, 2025

(54) GEL MATERIAL-FILLED POWER MODULE WITH A CIRCUIT CARRIER

(71) Applicant: Robert Bosch GmbH, Stuttgart (DE)

(72) Inventor: Irfan Aydogmus, Nuertingen (DE)

(21) Appl. No.: 19/055,617

(22) Filed: Feb. 18, 2025

(30) Foreign Application Priority Data
Feb. 26, 2024 (DE) 10 2024 201 719.1

(51) Int. Cl. H01L 23/24; H01L 25/07

(52) U.S. Cl. CPC H01L 23/24; H01L 25/072

(57) ABSTRACT

A power module with a circuit carrier. The power module includes a carrier substrate and an electrical insulation layer. The circuit carrier includes a first conductor structure with an external contact region and at least one second conductor structure with at least one external contact region and a further, third conductor structure, which includes at least one external contact region, having semiconductor components. A multifunctional frame and a frame are assigned to the power module. Groups of semiconductor components are arranged in a first plane spatially separated from a second plane in the multifunctional frame. The semiconductor components are electrically connected to one another by a first sintered connection with at least one first spacer or by a bonded connection with at least one bond wire. The second plane is at least partially enclosed laterally by the frame and is filled with a gel material.

### FIELD

The present invention relates to a power module with a circuit carrier comprising a carrier substrate and an electrical insulation layer. The circuit carrier has a first conductor structure with an external contact region, at least one second conductor structure with at least one external contact region, and a further, third conductor structure which comprises at least one external contact region.

### BACKGROUND INFORMATION

In the related art, power modules, which are installed for example in a power module bridge, are additionally molded. During molding, the power module is embedded in a solid protective housing, for example made of plastics material (molding compound). The molding compound is used to enclose and protect the interior of the power module. However, these enclosures of the power module by means of molding compound are not particularly resistant to cracks.

German Patent Application No. DE 11 2017 004 390 T5 describes a power module that has the following features: an insulating substrate having a front side to which a power semiconductor element is fastened; a base plate connected to a rear side of the insulating substrate; a housing fastened to the base plate and surrounding the insulating substrate; a cover fastened to the housing and forming a sealed region; and a silicone gel serving as a filling element which fills the entire sealed region and has an internal stress that acts as a compressive stress.

German Patent No. DE 10 2014 219 998 B4 describes a power module, in particular for providing a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the relevant first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces. Furthermore, the power module comprises at least two third contact faces on the surface, wherein the at least two second power transistors each have a further contact face on their sides facing away from the surface of the circuit carrier, and in each case one second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each have a further contact face on their sides facing away from the surface of the circuit carrier, and in each case one first power transistor of the at least two first power transistors is electrically conductively connected via its further contact face to the relevant contact region of the at least two contact regions of the second contact face that is located next to it. In this case, the at least two contact regions of the second contact face and the at least two second power transistors are arranged alternately one after the other in the longitudinal direction.

European patent No. EP 2 418 925 B1 describes an electrical contacting between a flexible film, which has at least one conductor track, and at least one electrical contact of a sensor device or control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

According to an example embodiment of the present invention, a power module is provided with a circuit carrier, which comprises a carrier substrate and an electrical insulation layer, wherein the circuit carrier comprises a first conductor structure with an external contact region and at least one second conductor structure with at least one external contact region and a further, third conductor structure, which comprises at least one external contact region, having semiconductor components that are arranged individually or in groups, in such a way that a multifunctional frame and a frame are assigned to the power module, wherein the groups of semiconductor components are arranged in a first plane, which is spatially separated from a second plane in the multifunctional frame, wherein the semiconductor components are electrically connected to one another by a sintered connection with the introduction of at least one first spacer or by a bonded connection with the introduction of at least one bond wire, wherein the second plane is at least partially enclosed laterally by the frame and is filled with a gel material.

A particularly advantageous structure is created by the solution according to the present invention by filling the power module with a gel material. The power module or a plurality of power modules are not typically enclosed with a molding compound, but are fastened to the cooling surface without a molding compound, wherein a frame is fastened to the cooling surface around the power module, wherein the volume enclosed by the frame is filled with the gel material in such a way that one or more power modules are covered with gel. A silicone gel is a semi-solid substance that contains a network of silicone polymers suspended in a liquid or viscous medium. Silicone gel is temperature-resistant and does not deform its structure. In contrast to a potting compound, such as a casting compound, the gel has a high degree of elasticity and flexibility and is therefore able to absorb and distribute thermal stresses without cracking or breaking. In addition, silicone gel has a lower thermal conductivity coefficient, as a result of which the insulation is improved and local temperature differences can be better limited.

In a further advantageous embodiment of the power module provided according to the present invention, the semiconductor components are arranged individually or in groups on a base of the power module.

In the power module provided according to the present invention, the spacer is arranged in the region of a joint between a bottom side of the multifunctional frame and a top side of the power module. Component tolerances and/or manufacturing tolerances that arise when joining the components in question can be compensated for via the at least one spacer provided within the at least one sintered connection. Due to the installation of the spacers in a power module, short circuits can also be avoided. In addition, the installation of spacers provides optimal heat dissipation, which leads to an improvement in the performance and reliability of the power module. Furthermore, spacers with semiconductor switches and circuit boards, for example, are coupled to one another by sintered connections. The advantage of the sintered connection is, for example, the elimination of additional connecting elements such as screws, adhesives or welds, as a result of which weak points or sources of error associated with the use of such connecting elements are eliminated. In addition, the sintered connection achieves a homogeneous stress distribution on the components of the power module, since the stresses are evenly distributed over the entire joining surface. This can reduce stress concentrations and improve the overall stability of a connection.

In a further advantageous embodiment of the power module provided according to the present invention, the spacer is arranged in the region of a joint between a bottom side of the multifunctional frame and a top side of the power module.

5 Substitute Specification

In a further advantageous embodiment of the power module provided according to the present invention, the sintered connection has a first, a second and a third sintered layer.

In a further advantageous embodiment of the power module provided according to the present invention, the first sintered connection can be replaced by a first welded connection or a first soldered connection, wherein in both cases a structural unit with a first, second and third layer is created.

In a further advantageous embodiment of the power module provided according to the present invention, the power module has a second sintered connection.

In a further advantageous embodiment of the power module provided according to the present invention, the second sintered connection has a fourth and a fifth sintered layer.

In a further advantageous embodiment of the power module provided according to the present invention, the second sintered connection can be replaced by a second welded connection or a second soldered connection, wherein in both cases a structural unit with the first and the second layer is created.

In a further advantageous embodiment of the power module provided according to the present invention, the power module is connected to a cooling surface via a third soldered connection, an adhesive connection or a third sintered connection.

In a further advantageous embodiment of the power module provided according to the present invention, the multifunctional frame is arranged above or below the power module, seen in the Z direction.

In a further advantageous embodiment of the power module provided according to the present invention, current-carrying components, in particular a T+ bridge and a T− bridge, are formed one above the other or next to the other in the multifunctional frame in such a way that a low-inductance connection is formed.

In the power module according to the present invention, the multifunctional frame and the power module are separated from one another in the Z direction and electrically connected to one another by an integral connection, which is preferably formed as a soldered connection and a welded connection. The current-carrying contact faces preferably extend in a multifunctional frame that can be placed above or below the power module, while the semiconductor components, which are arranged individually or in groups on the bottom side of the power module, are placed therein. The cooling surface is placed in such a way that it is ensured that the region with the highest heat loss, in particular the bottom side of the power module, receives the necessary cooling. As a result, it is ensured that the cooling surface remains thermally connected throughout the entire process. In addition, the soldered connection makes possible an efficient unevenness compensation for compensating for any unevenness and/or irregularities between the surface of the power module and the cooling surface, in order to achieve an improved contact face and thus optimized heat transfer. In addition, the soldered connection has a low electrical conductivity compared to some other connecting materials, as a result of which short circuits in an electrically insulating connection are advantageously prevented.

The introduction of spacers advantageously ensures an efficient alignment and placement of the components of the power module, while at the same time optimizing heat dissipation. The power module according to the present invention is characterized in that an optimized structural strength between the components of the power module and the multifunctional frame is achieved by a sintered connection of the spacers, wherein the sintered connection effectively dampens vibrations, shocks and/or other mechanical loads. In addition, due to the sintered connection, a precise shaping of the connections, which ensures a correct alignment and positioning, is achieved, as a result of which component or manufacturing tolerances are compensated for.

According to an example embodiment of the present invention, the power module is advantageously connected to the multifunctional frame via the bonded connection, the first welded connection, the first sintered connection or a first soldered connection. Due to the soldered, bonded and welded connection, an efficient connection is achieved in such a way that, for example, surface unevenness of the power module and/or the multifunctional frame is compensated for due to these types of connection. Furthermore, the soldered connection and the welded connection can ensure a mechanically strong connection. In addition, due to the soldered connection, differences in thermal expansion between the power module and the multifunctional frame can be compensated for, in order to effectively avoid possible stresses and cracks due to temperature fluctuations. The alternative bonded connection minimizes unwanted effects such as inductance and capacitance, thus ensuring optimized signal integrity and performance. A bonded connection also has good mechanical stability, wherein vibrations, shock loads and other mechanical stresses are effectively compensated for.

Thanks to the advantageously low-inductance current-carrying paths, a significant reduction in switching losses can be achieved. In addition, low-inductance paths help minimize voltage spikes, in order to protect the integrity of semiconductor devices and other electronic components, in particular in power modules with fast switching operations.

### BRIEF DESCRIPTION OF THE DRAWINGS

Example embodiments of the present invention are explained in greater detail with reference to the figures and the following description.

FIG. 1 is a plan view of a first circuit carrier of a power module, which is composed of a carrier substrate and an arrangement of semiconductor components, according to an example embodiment of the present invention.

FIG. 2 is a plan view of a power module with cooling and layout surfaces separated from one another with laterally arranged regions for press-fit pins, according to an example embodiment of the present invention.

FIG. 3 is an exploded view of an arrangement of power modules, multifunctional frame, gel material and the cooling surface, according to an example embodiment of the present invention.

FIG. 4 is an enlarged view of a first sintered connection, according to an example embodiment of the present invention.

FIG. 5 is an enlarged view of a second sintered connection, according to an example embodiment of the present invention.

FIG. 6 is an enlarged view of a bonded connection, according to an example embodiment of the present invention.

### DETAILED DESCRIPTION OF EXAMPLE EMBODIMENTS

In the following description of the example embodiments of the present invention, identical or similar elements are denoted by the same reference signs, and a repeated description of these elements in individual cases is dispensed with. The figures show the subject matter of the present invention only schematically.

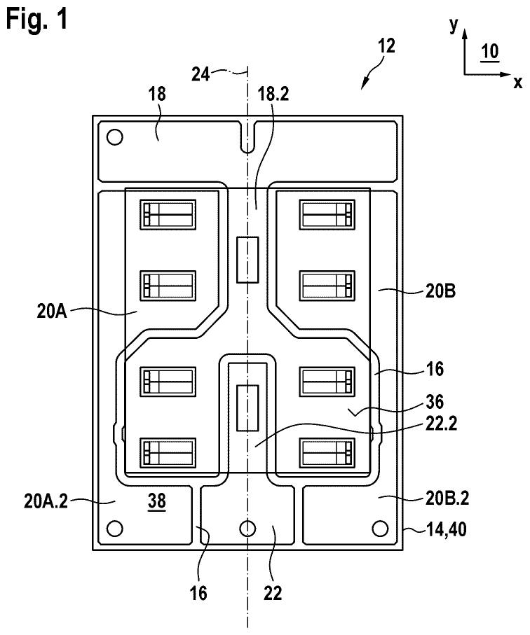

FIG. 1 is a plan view of a power module 12, in particular of its circuit carrier 14.

From the plan view according to FIG. 1 it can be seen that a carrier substrate 40 of the circuit carrier 14 is provided with a plurality of conductor structures 18, 20A, 20B, 22. The circuit carrier 14 extends in an X, Y plane 10, wherein the circuit carrier 14 is formed with an electrical insulation layer 16. On said insulation layer, separated by channel-shaped interruptions, there is a first conductor structure 18 which has an external contact region 18.2. Furthermore, second conductor structures 20A, 20B are located symmetrically to a central longitudinal axis 24 of the power module 12 opposite one another on the circuit carrier 14. Each of the two second conductor structures 20A, 20B comprises an external contact region 20A.2, 20B.2. Finally, a third conductor structure 22, which has at least one external contact region 22.2, is applied to the circuit carrier 14 or to its electrical insulation layer 16.

The aforementioned conductor structures 18, 20A, 20B, 22 are electrically separated from one another and are applied to the circuit carrier 14 substantially symmetrically to the central longitudinal axis 24. As the carrier substrate 40 of the circuit carrier 14, AMB (active metal brazing, (OFC (oxygen-free copper)/Si₃N₄/OFC)) is advantageously selected.

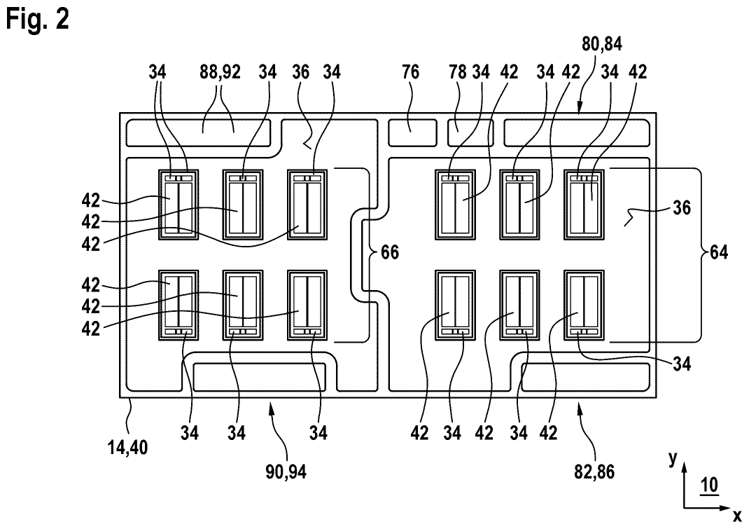

The representation in FIG. 2 shows a plan view of the power module 12. In this schematic representation, semiconductor components 42 are arranged on active surfaces 36, which components can be, for example, transistors, MOSFETs, IGBTs, diodes or other semiconductor components that can be used as semiconductor switches. FIG. 2 shows that a first group 64 of semiconductor components 42 is accommodated on the active surfaces 36. The individual semiconductor components 42 can, for example, be formed as MOSFETs and comprise control terminals 34 on their outer sides, via which the individual semiconductor components 42 of the first group 64 of semiconductor components 42, which is not shown in detail, can be controlled. Analogously to the first group 64, a second group 66 of semiconductor components 42 is arranged, which can also be MOSFETs, on the outer region of which control terminals 34 are formed in each case. An arrangement of the semiconductor components 42 in groups 64, 66 is not absolutely necessary, these can also be arranged individually according to the scaling, i.e. not in groups 64, 66. The semiconductor components 42 of the second group 66 of semiconductor components 42 can be controlled from the outside via the control terminals 34, but this is not shown in detail in the representation according to FIG. 2.

Furthermore, it can be seen from the plan view according to FIG. 2 that in the X, Y plane 10 shown in FIG. 2, regions are provided on the longitudinal sides of the circuit carrier 14 in the form of a carrier substrate 40, in which regions press-fit pins 76-94 protrude into the plane of the drawing according to FIG. 2. In detail, these are first and second press-fit pins 76, 78 as well as third and fourth press-fit pins 80, 82 and, arranged opposite one another, fifth and sixth press-fit pins 84, 86. In the region of the opposite end face of the circuit carrier 14, seventh and eighth press-fit pins 88, 90 are provided, as well as ninth and tenth press-fit pins 92, 94.

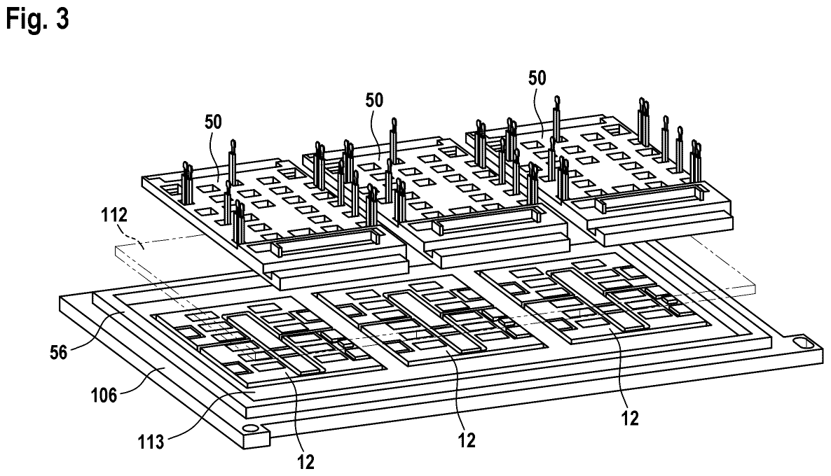

FIG. 3 shows an arrangement of the power modules 12, the multifunctional frame 50, the gel material 112 and the cooling surface 106 with a frame 56, wherein the frame 56 is made of plastics material, for example. FIG. 3 shows three power modules 12 positioned within the frame 56, wherein each power module 12 is assigned a multifunctional frame 50. FIG. 3 also shows a region 113 to be filled with gel material 112. The region 113 to be filled with gel material is located within the volume enclosed by the frame 56. The enclosed volume can be influenced, for example, by corresponding dimensions of the frame 56. This can be effected, for example, by determining the length, width and depth dimensions of the power modules 12 to be installed within the frame 56.

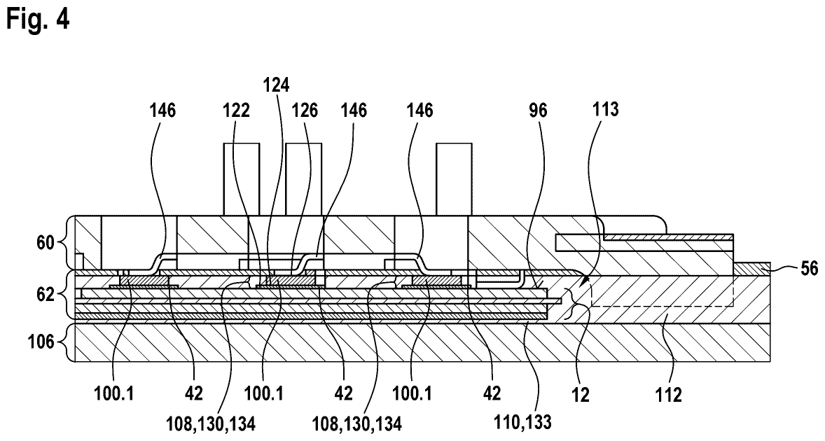

FIG. 4 is an enlarged view of the first sintered connection 130. The first sintered connection 130 shown in FIG. 4 has a first sintered layer 122, with which a semiconductor component 42 is connected to the base 96 of the power module 12. Furthermore, the first sintered connection 130 has a second sintered layer 124, with which the semiconductor component 42 is connected to a first spacer 100.1, and a third sintered layer 126, which connects the first spacer 100.1 to a contact strip 146 of the multifunctional frame 50, so that the heat of the contact strips 146 can be dissipated via the third soldered connection 110, the adhesive connection 110 or third sintered connection 133 through the base surface 96 to the cooling surface 106. The first sintered connection 130 shown in FIG. 4 advantageously ensures efficient heat dissipation and electrical reliability. For example, the first, second and third sintered layers 122, 124, 126 of the first sintered connection 130 are formed using conductive metal powders as sintered material such as silver or copper, wherein excellent electrical conductivity and thermal conductivity are achieved by the first sintered connection 130 according to the present invention with the electrically conductive material. For example, the first, second and third sintered layers 122, 124, 126 of the first sintered connection 130 can be applied by applying the electrically conductive metal powder to a surface of the components of the power module 12 or the multifunctional frame 50 to be connected to one another. Furthermore, sintered particles of the sintered material, in particular metal powder, can be fused to one another and to the surfaces, for example by controlled heating to an adjusted temperature, in order to produce a solid and thermal connection. Alternatively, the first sintered connection 130 can be replaced by a first welded connection 134 or a first soldered connection 108

The connection of the base 96 of the power module 12 to the cooling surface 106 shown in FIG. 4 can be variably effected by a second soldered connection 110 (an adhesive connection 110 or a third sintered connection 133). All connections of the base 96 of the power module 12 to the cooling surface 106 are characterized by efficient heat conduction of the heat of the contact strip 146 dissipated through the base 96. These connection options also offer optimal adjustment to the tolerances of the surface of the power module 12 to be contacted with the cooling surface 106, since uniform surface contact is provided by the connection options shown in FIG. 4.

Furthermore, FIG. 4 shows an arrangement of the first plane 60, the second plane 62 and the cooling surface 106, wherein the second plane 62 is arranged on the cooling surface 106 and the first plane is arranged on the second plane 62. A frame 56 is also shown. The frame 56 surrounds the power module 12 laterally. Furthermore, a frame 56 with a region to be filled 113 is shown, which frame is filled with gel material 112.

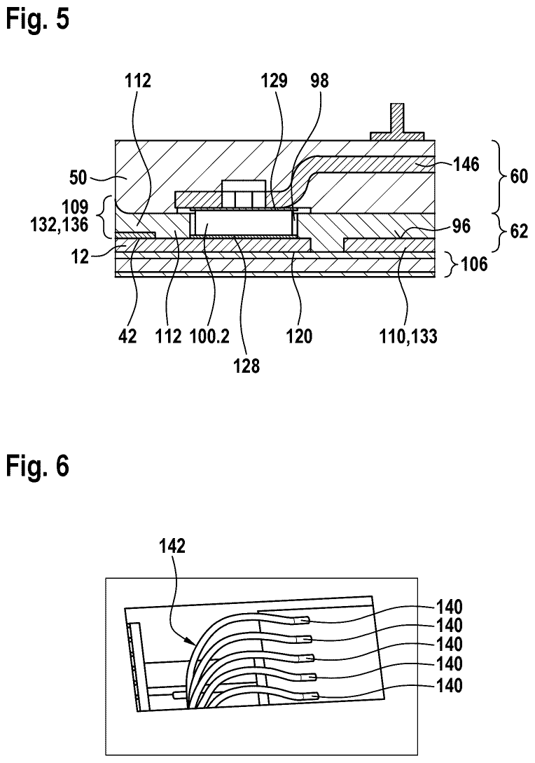

FIG. 5 is an enlarged view of the second sintered connection 132.

The second sintered connection 132 shown in FIG. 5 comprises the fifth sintered layer 129, with which a second spacer 100.2 is connected to the bottom side of the phase bridge 136, and the fourth sintered layer 128, with which the second spacer 100.2 is connected to the base 96 of the power module 12. The second spacer 100.2 is located on the base 96 of the power module 12, so that the heat of the phase bridge 136 can be dissipated through the base surface 96 via the third sintered connection 133 or the soldered or adhesive connection 110 to the cooling surface 106. Alternatively, the second sintered connection 132 can be replaced by a second welded connection 136 or a second soldered connection 109. FIG. 5 also shows the filling of the second plane 62 with gel material 112.

FIG. 6 is an enlarged view of a bonded connection 142.

The bonded connection 142 shown in FIG. 6 comprises an electrical connection of the semiconductor components 42 of the power module 12 to the multifunctional frame 50 via the bond wires 140, wherein the bond wires 140 are attached to a contact face 102 of the semiconductor component 42 of the power module 12 and to the connection pads 138 of the multifunctional frame 50 as an alternative to introducing the spacers 100.1, 100.2. Alternatively, an electrical connection between the semiconductor components 42 of the power module 12 and the multifunctional frame 50 can also be established by introducing the circuit board and the bonded connection 142.

The present invention is not limited to the example embodiments described here and the aspects emphasized therein. Rather, a large number of modifications are possible within the scope of the present invention, which are within the scope of the activities of a person skilled in the art in view of the disclosure herein.

1-11. (canceled)

12. A power module, comprising:
a circuit carrier, which includes a carrier substrate and an electrical insulation layer, wherein the circuit carrier includes a first conductor structure with an external contact region, at least one second conductor structure with at least one external contact region, and a third conductor structure which includes at least one external contact region, having semiconductor components that are arranged individually or in groups;
wherein, a multifunctional frame and a frame are assigned to the power module, wherein the groups of semiconductor components are arranged in a first plane which is spatially separated from a second plane in the multifunctional frame;
wherein the semiconductor components are electrically connected to one another: (i) by a first connection with an introduction of at least one first spacer or (ii) by a bonded connection with an introduction of at least one bond wire;
wherein the second plane is at least partially enclosed laterally by the frame and is filled with a gel material.

13. The power module according to claim 12, wherein the semiconductor components are arranged on a base of the power module individually or in groups.

14. The power module according to claim 12, wherein the spacer is arranged in a region of a joint between a bottom side of the multifunctional frame and a top side of the power module.

15. The power module according to claim 12, wherein the first connection is a first sintered connection having a first sintered layer, a second sintered layer, and a third sintered layer.

16. The power module according to claim 12, wherein the first connection is a welded connection or a first soldered connection, wherein the first connection includes a first layer, a second layer, and a third layer.

17. The power module according to claim 15, wherein the power module has a second sintered connection.

18. The power module according to claim 17, wherein the second sintered connection has a fourth sintered layer and a fifth sintered layer.

19. The power module according to claim 12, wherein the power module includes a second welded connection or a second soldered connection, wherein the second welded connection or the second soldere connection has a first layer and a second layer.

20. The power module according to claim 19, wherein the power module is connected to a cooling surface via a third soldered connection, an adhesive connection, or a third sintered connection.

21. The power module according to claim 12, wherein the multifunctional frame is arranged above or below the power module, in a Z direction.

22. The power module according to claim 12, wherein current-conducting components, including a T+ bridge and a T−bridge, are formed one above the other or next to one another in the multifunctional frame in such a way that a low-inductance connection is formed.
